(19) United States
(12) Patent Application Publication
(10) Pub. No.: US 2009/0029287 A1
(43) Pub. Date: Jan. 29, 2009

(54) PHOTOSENSITIVE RESIN COMPOSITION

(75) Inventors: Takaaki Kobayashi, Tokyo (JP); Masashi Kimura, Tokyo (JP)

Correspondence Address: GREENBLUM & BERNSTEIN, P.L.C., 1950 ROLAND CLARKE PLACE, RESTON, VA, 20191, US

(73) Assignee: ASAHI KASEI EMD CORPORATION, Tokyo (JP)

(21) Appl. No.: 12/097,623

(22) PCT Filed: Jan. 19, 2007
(86) PCT No.: PCT/JP2007/050793

§ 371 Date: Jun. 16, 2008

(30) Foreign Application Priority Data
Jan. 24, 2006 (JP) 2006-015218
Jan. 25, 2006 (JP) 2006-016539

(51) Int. Cl. G03F 7/028; G03F 7/09; G03F 7/20

(52) U.S. Cl. 430/280.1; 430/281.1; 430/325

(57) ABSTRACT

The present invention provides a photosensitive resin composition and a resin film obtained from the photosensitive resin particularly useful for a buffer coating material for LSI chips. For this purpose, there are used a photosensitive resin composition, comprising: 100 parts by weight of a polycondensate obtained by condensation-polymerizing compounds represented by specific chemical formulas in a specific mixing ratio, 0.01 to 5 parts by weight of a photopolymerization initiator and 1 to 30 parts by weight of a specific organosilane, and a resin film obtained by coating the photosensitive resin composition on a silicon wafer surface, exposing the coated film, developing the exposed film, and curing the developed film.

### TECHNICAL FIELD

The present invention relates to a photosensitive resin composition useful for producing electric and electronic materials such as semiconductor devices and multilayer interconnection boards, and to a resin film obtained from the photosensitive resin composition. More particularly, the present invention relates to a photosensitive resin composition suitable as a buffer coating material for LSI chips and an insulating material for forming rewiring layers, and to an insulating resin film obtained from the photosensitive resin composition.

### BACKGROUND ART

The performance requirement for a buffer coating material for LSI chips and an insulating material for forming rewiring layers is becoming more severe with finer design rules for LSIs. Specifically, high resolution, low-temperature cure, low stress, and the like are required. In particular, the stress resistance and heat resistance of a low-k material used in advance of the buffer coating material are becoming increasingly weaker, and copper for rewiring also tends to have greater film thickness due to the increase of current density. For this reason, it is necessary to use a material which satisfies a thick film, flatness, low stress, and low-temperature cure, in addition to the conventional performance such as high resolution, chemical resistance, and temperature stress resistance, as an upper-layer buffer coating material.

As a buffer coating material, for example, a photosensitive polyimide which is disclosed in any of Patent Documents 1 to 5 has been used as one of the representative examples thereof. However, a photosensitive polyimide also has many problems and especially has a significant defect that it is inferior in the flatness after curing. A buffer coating material that satisfies all of the above-mentioned requirements when it is used singly is not known.

How to use a photosensitive polyimide as a buffer coating material will be shown briefly. First, a polyamide having a double bond in a side chain is used as a photosensitive polyimide precursor, and it is spin-coated on an LSI wafer. Subsequently, the wafer is exposed to optically crosslink only the double bond in the side chain and then developed to form a desired pattern. Then, the wafer is heat-treated to change the polyamide in the pattern to a polyimide structure by dehydration, thus yielding a buffer coating material excellent in heat resistance. Note that crosslinked chains are also decomposed and volatilized by the heat treatment.

The photosensitive polyimide can form strong adhesion with a substrate in the above dehydration process. Photosensitive polyimides are excellent also in chemical resistance to organic alkali solutions, for example, a mixed solvent of dimethylsulfoxide (DMSO) and tetramethylammonium hydride (TMAH) or the like because of a strong molecular structure thereof.

However, when a photosensitive polyimide is used as a buffer coating material, there is a problem that the film is densified through the dehydration and the decomposition and volatilization of crosslinked chains by heat treatment to thereby decrease the thickness by about 40 percents.

Further, Patent Document 6 discloses ORMOCER (registered trademark) ONE, a coating material manufactured by Fraunhofer ISC, Germany, which comprises an organosilane having a polymerizable group using Ba(OH)₂ (barium hydroxide) as a catalyst and an organosilane having a hydrolytically reactive site. ORMOCER (registered trademark) ONE can be cured at a low temperature of 150° C., and a cured product thereof has excellent characteristics such as a heat resistance of 300° C. or more, a low residual stress of 10 Mpa or less, and a flatness of 3% or less. However, as shown in the Comparative Example to be described below, the cured product of ORMOCER (registered trademark) ONE is poor in adhesion with metal.

Furthermore, the cured product of ORMOCER (registered trademark) ONE has a low elongation because it is a resin having a structure where rigid nanosized segments of a siloxane Si—O bonding skeleton are combined to form a three-dimensional network with a methacrylic group.

### [Patent Document 1] JP-A-06-053520

### [Patent Document 2] JP-A-06-240137

### [Patent Document 3] JP-A-09-017777

### [Patent Document 4] JP-A-11-297684

### [Patent Document 5] JP-A-2002-203851

### [Patent Document 6] Canadian Patent No. 238756

### DISCLOSURE OF THE INVENTION

### Problems to be Solved by the Invention

An object of the present invention is to provide a photosensitive resin composition useful for producing electric and electronic materials such as semiconductor devices and multilayer interconnection boards, and in particular, to provide a photosensitive resin composition capable of forming a resin film having a siloxane structure which provides an excellent flatness as a buffer coating material for LSI chips, and which has improved adhesion with substrate metal (such as copper and aluminum) wiring and improved elongation.

### Means for Solving the Problems

In order to solve the above problems, the present inventors have studied a photosensitive resin having a methacrylic group or an acrylic group and containing a siloxane structure, as a new material. As a result, it has been found that a photosensitive resin composition having an excellent adhesion and elongation can be obtained by further incorporating an organosilane having an epoxy group, an acrylic group, or a methacrylic group. The present invention has been completed, based on this finding. More specifically, the present invention is as follows:

(1) A photosensitive resin composition, comprising:
100 parts by weight of a polycondensate obtained by condensation-polymerizing compounds represented below by a) and b) in a mixing ratio of a)/b) of 60 mol %/40 mol % to 40 mol %/60 mol % for 0.1 to 10 hours at a temperature of 40 to 150° C., 0.01 to 5 parts by weight of a photopolymerization initiator, and
1 to 30 parts by weight of at least one organosilane represented below by c),
wherein
a) represents R¹ₐR²_{b}Si(OR³)_{4-a-b}
wherein R¹ represents a group having 2 to 17 carbon atoms which contains at least one group selected from the group consisting of an epoxy group and a carbon-carbon double bond group; R² and R³ independently represent a methyl group or an ethyl group; a represents an integer selected from 1 and 2; b represents an integer selected from 0 and 1; and a+b does not exceed 2;
b) represents R₂Si(OH)₂
wherein R represents one or more groups selected from the group consisting of an aryl group having 6 to 20 carbon atoms and an alkylaryl group having 6 to 20 carbon atoms; and
c) represents R⁴Si(OR⁵)₃
wherein R⁴ represents an organic group containing a group having 2 to 17 carbon atoms which has any one of an epoxy group, an acrylic group, and a methacrylic group; and R⁵ is a methyl group or an ethyl group.
(2) A photosensitive resin composition according to (1), characterized in that the above compound a) is 3-methacryloxypropyltrimethoxysilane, and the above compound b) is diphenylsilanediol.
(3) A photosensitive resin composition according to (1) or (2), characterized in that the above organosilane c) is at least one compound selected from the group consisting of 3-glycidyloxypropyltrimethoxysilane, 3-methacryloxypropyltrimethoxysilane, and 3-acryloxypropyltrimethoxysilane.
(4) A process for producing a resin film having a siloxane structure, characterized by comprising the steps of coating the photosensitive resin composition according to any one of (1) to (3) on a silicon wafer surface, exposing the coated film, developing the exposed film, and curing the developed film.
(5) A layered resin article obtained by layering a resin film on a silicon wafer surface by the process for producing a resin film according to (4).

### ADVANTAGES OF THE INVENTION

The present invention can provide a photosensitive resin composition useful for producing electric and electronic materials such as semiconductor devices and multilayer interconnection boards, and in particular, a photosensitive resin composition capable of forming a resin film having a siloxane structure which provides an excellent flatness as a buffer coating material for LSI chips and has improved adhesion with substrate metal wiring and elongation.

### BEST MODE FOR CARRYING OUT THE INVENTION

### (1) Photosensitive Resin Composition

The photosensitive resin composition according to the present invention is a photosensitive resin composition, comprising:

100 parts by weight of a polycondensate obtained by condensation-polymerizing compounds represented by a) and b) in a mixing ratio of a)/b) of 60 mol %/40 mol % to 40 mol %/60 mol % for 0.1 to 10 hours at a temperature of 40 to 150° C., 0.01 to 5 parts by weight of a photopolymerization initiator, and
1 to 30 parts by weight of at least one organosilane represented by c),
wherein
a) represents R¹ₐR²_{b}Si(OR³)_{4-a-b}
wherein R¹ represents a group having 2 to 17 carbon atoms which contains at least one group selected from the group consisting of an epoxy group and a carbon-carbon double bond group; R² and R³ independently represent a methyl group or an ethyl group; a represents an integer selected from 1 and 2; b represents an integer selected from 0 and 1; and a+b does not exceed 2;
b) represents R₂Si(OH)₂
wherein R represents one or more groups selected from the group consisting of an aryl group having 6 to 20 carbon atoms and an alkylaryl group having 6 to 20 carbon atoms; and
c) represents R⁴Si(OR⁵)₃
wherein R⁴ represents an organic group containing a group having 2 to 17 carbon atoms which has any one of an epoxy group, an acrylic group, and a methacrylic group; and R⁵ is a methyl group or an ethyl group.

The temperature in the process for obtaining the above polycondensate is from 40 to 150° C., preferably from 50 to 90° C., more preferably from 70 to 90° C. The temperature is 40° C. or more in terms of the reactivity of polycondensation, and it is 150° C. or less in terms of protection of a functional group. The time is from 0.1 to 10 hours, preferably 0.5 to 5 hours, more preferably 0.5 to 3 hours. The time is 0.1 hour or more in terms of the reactivity of polycondensation, and it is 10 hours or less in terms of protection of a functional group.

In the process for obtaining the above polycondensate, a catalyst is used, and water is not intended to be added. Trivalent or tetravalent metal alkoxides can be used as a catalyst. Specific examples include trimethoxyaluminum, triethoxyalminum, tri-n-propoxyaluminum, tri-iso-propoxyaluminum, tri-n-butoxyaluminum, tri-iso-butoxyaluminum, tri-sec-butoxyaluminum, tri-tert-butoxyaluminum, trimethoxyboron, triethoxyboron, tri-n-propoxyboron, tri-iso-propoxyboron, tri-n-butoxyboron, tri-iso-butoxyboron, tri-sec-butoxyboron, tri-tert-butoxyboron, tetramethoxysilane, tetraethoxysilane, tetra-n-propoxysilane, tetra-iso-propoxysilane, tetra-n-butoxysilane, tetra-iso-butoxysilane, tetra-sec-butoxysilane, tetra-tert-butoxysilane, tetramethoxygermanium, tetraethoxygermanium, tetra-n-propoxygermanium, tetra-iso-propoxygermanium, tetra-n-butoxygermanium, tetra-iso-butoxygermanium, tetra-sec-butoxygermanium, tetra-tert-butoxygermanium, tetramethoxytitanium, tetraethoxytitanium, tetra-n-propoxytitanium, tetra-iso-propoxytitanium, tetra-n-butoxytitanium, tetra-iso-butoxytitanium, tetra-sec-butoxytitanium, tetra-tert-butoxytitanium, tetramethoxyzirconium, tetraethoxyzirconium, tetra-n-propoxyzirconium, tetra-iso-propoxyzirconium, tetra-n-butoxyzirconium, tetra-iso-butoxyzirconium, tetra-sec-butoxyzirconium, and tetra-tert-butoxyzirconium. Alternatively, barium hydroxide, sodium hydroxide, potassium hydroxide, strontium hydroxide, calcium hydroxide, and magnesium hydroxide may be used as a catalyst. Especially, barium hydroxide, strontium hydroxide, tetra-tert-butoxytitanium, and tetra-tert-propoxytitanium are preferred. For achieving a rapid and uniform polymerization reaction, the catalyst is preferably in a liquid state in the reaction temperature range.

The amount of the catalyst added is preferably from 1 to 10 mol, more preferably from 1 to 3 mol, based on 100 mol of the compound b).

Here, as for the mixing mol % of the compounds represented by a) and b), the ratio of compound a)/compound b) is from 60 mol %/40 mol % to 40 mol %/60 mol %, preferably from 55 mol %/45 mol % to 45 mol %/55 mol %, more preferably from 52 mol %/48 mol % to 48 mol %/52 mol %. The mixing mol % of the compound a) and the compound b) is from 60 mol %/40 mol % to 40 mol %/60 mol % in terms of the stability of the photosensitive resin composition.

Further, the organosilane c) is from 1 to 30% by weight, preferably from 5 to 20% by weight, more preferably 7 to 12% by weight, based on the polycondensate. It is 1% by weight or more in terms of developing adhesion to a substrate metal and is 30% by mass or less in terms of the storage stability of the photosensitive resin composition.

Examples of R¹ in the above compound a) include a vinyl group, a 2-(3,4-epoxycyclohexyl) group, a 3-glycidoxypropyl group, a styryl group, a 3-(meth)acryloxypropyl group, a 2-(meth)acryloxyethyl group, a (meth)acryloxymethyl group. Here, (meth)acryl represents an acrylic group and a methacrylic group, hereinafter the same. Specific examples include 3-methacryloxypropyltrimethoxysilane, 3-acryloxypropyltrimethoxysilane, 3-methacryloxypropylmethyldimethoxysilane, 3-vinylethylenetrimethoxysilane, and 3-vinylmethylenetrimethoxysilane. Among these, 3-methacryloxypropyltrimethoxysilane (hereinafter may be referred to as MEMO) is most preferred.

Examples of R in the above compound b) include a phenyl group, a tolyl group, a xylyl group, a trimethylphenyl group, and a naphthyl group. Among these, a phenyl group can be preferably used. Specifically, diphenylsilanediol (hereinafter may be referred to as DPD) is used preferably.

Specific examples of the above organosilane c) include 3-glycidyloxypropyltrimethoxysilane, 3-methacryloxypropyltrimethoxysilane, and 3-acryloxypropyltrimethoxysilane. Among these, 3-glycidyloxypropyltrimethoxysilane (hereinafter may be referred to as GLYMO) and MEMO are more preferred.

As a polycondensate of the above compounds a) and b), there is mentioned a polycondensate obtained by using MEMO as the compound a), DPD as the compound b), and Ba(OH)₂ as a catalyst and subjecting them to polycondensation at 80° C. for 0.5 hour. This polycondensate is available from Fraunhofer ISC of Germany as ORMOCER (registered trademark) ONE.

As a photopolymerization initiator in the present invention, there is suitably used a known photopolymerization initiator having absorption at 365 nm, for example, 2-benzyl-2-dimethylamino-4′-morpholinobutyrophenone (IRGACURE 369). Examples of other known initiators include benzophenone, 4,4′-diethylaminobenzophenone, diethylthioxantone, ethyl-p-(N,N-dimethylaminobenzoate), and 9-phenylacridine. The amount of the photopolymerization initiator added is preferably from 0.01 to 5 parts by weight, more preferably from 0.3 to 3 parts by weight, most preferably from 0.5 to 2 parts by weight, based on 100 parts by weight of the above polycondensate.

### (2) A Method for Producing a Resin Film Having a Siloxane Structure

The photosensitive resin layer comprising a photosensitive resin composition can be formed on a substrate such as a silicon wafer by a method of coating, for example, using a spin coater, a bar coater, a blade coater, a curtain coater, a screen printer, or the like, or spray-coating using a spray coater or the like.

The photosensitive resin layer obtained may be pre-baked by air-drying, heating in an oven or on a hot plate, vacuum-drying, or the like.

The photosensitive resin layer obtained is exposed to an ultraviolet or other ray source through a mask using an exposure apparatus such as a contact aligner, a mirror projection aligner, and a stepper. The light source preferably has the wavelength of i-line light in terms of the resolution of a cured pattern of the resin layer after exposure and handling properties, and the apparatus is preferably a stepper.

Then, the exposed resin layer is developed. The unexposed portion of the photosensitive resin layer is removed by development. Thereby, a cured pattern can be obtained. The development can be performed by selecting any method from known conventional methods for developing photoresists, for example, a rotational spray method, a paddle method, and a method of dipping with sonication.

As a developer used, a combination of a good solvent and a poor solvent to the above polymer precursor is preferred. Examples of the good solvent used include N-methylpyrrolidone, N-acetyl-2-pyrrolidone, N,N′-dimethylacetamide, cyclopentanone, γ-butyrolactone, and a-acetyl-γ-butyrolactone. Examples of the poor solvent used include toluene, xylene, methanol, ethanol, isopropyl alcohol, and water. The proportion of the poor solvent to the good solvent is adjusted according to the solubility of the photosensitive resin composition having a siloxane structure. The solvents can also be used in combination.

The cured pattern of the resin having a siloxane structure thus obtained is cured to combine unreacted methacrylic groups with each other to obtain a resin film having a siloxane structure.

The curing can be performed, for example, with a hot plate, an oven, and a temperature-rising type oven in which a temperature program can be set. As the atmospheric gas for curing, air may be used, or an inert gas such as nitrogen or argon may be used. Curing temperature is preferably from 150 to 250° C. Curing time is preferably from 2 to 4 hours.

The thickness of the resin film having a siloxane structure, which varies according to applications, is preferably from 10 to 100 μm, more preferably from 10 to 50 μm, further preferably 20 to 40 μm.

### EXAMPLES

Next, the present invention will be described further in detail with reference to Examples.

### Example 1

1) To 100 parts by weight of ORMCER (registered trademark) ONE (having a polycondensation molar ratio of DPD/MEMO of 1:1) manufactured by Fraunhofer ISC, was added 1 part by weight of an optical radical polymerization initiator IRGACURE 369 (manufactured by Ciba-Geigy) followed by mixing. The resulting mixture was filtered through a 0.2 μm mesh filter. Then, 10 parts by weight of GLYMO were added to 100 parts by weight of ORMCER (registered trademark) ONE at room temperature followed by mixing to form a photosensitive resin composition. The final viscosity was 15 poise.
2) The resulting photosensitive resin composition was spin-coated at 1,500 rpm for 40 seconds, yielding a spin-coated film having a thickness of 20 μm on an LSI wafer.
3) The spin-coated film was pre-baked at 80° C. for 1 minute to remove volatile residue, where neither film shrinkage nor reduction in flatness was observed.
4) The film was exposed to UV (wavelength of 365 nm) using a negative type mask to crosslink the same. The amount of light is 200 mJ/cm².
5) The crosslinked film was developed for 60 seconds using a 1:1 mixed solution of MIBK (methyl isobutyl ketone) and IPA (isopropyl alcohol) and subjected to rinse washing with IPA to form a via hole pattern having a diameter of 10 μm.
6) The film with a via hole pattern formed therein was post-baked at 80° C. for 1 minute and finally cured in N₂ at 150° C. for 3 hours to complete the curing.
7) A Cu rewiring layer was formed as the second layer by subjecting the cured film to copper plating, forming a resist pattern on the copper plate using a known photoresist, etching the unnecessary copper plate layer, and removing the resist.

### Example 2

This experiment was performed in the same manner as in Example 1 except that 3% by weight of MEMO was added in place of adding 10% by weight of GLYMO in Example 1.

### Example 3

This experiment was performed in the same manner as in Example 1 except that the step 1) in Example 1 was changed as follows.

1) A round-bottom flask of 500 ml was charged with 0.1 mol (21.63 g) of DPD, 0.1 mol (23.74 g) of MEMO, and tetra-tert-butoxytitanium in an amount of 2.2 mol (0.748 g) based on 100 mol of DPD. The flask was fitted with a cooler and gradually heated from room temperature to 80° C. in an oil bath. The start of reflux by produced methanol was observed at 80° C., and then the reflux was continued for one hour at the same temperature. Then, the cooler was taken, and methanol was removed by vacuum evaporation at the same temperature. The degree of vacuum was gradually increased so that bumping might not happen. When the degree of vacuum reached 3 torr, the vacuum suction was continued at 80° C. for 2 hours with agitation, and finally the degree of vacuum was returned to ordinary pressure to finish the removal of methanol. A transparent polycondensate obtained was cooled to room temperature. To 100 parts by weight of the polycondensate obtained was added 1 part by weight of IRGACURE 369 (manufactured by Ciba-Geigy) as a photopolymerization initiator, and the resulting mixture was filtered with a 0.2 μm mesh filter. Then, 3 parts by weight of MEMO were added at room temperature to 100 parts by weight of the polycondensate obtained to form a photosensitive resin composition. The final viscosity was 15 poise.

### Comparative Example 1

This experiment was performed in the same manner as in Example 1 except that no GLYMO was mixed.

In Examples 1 to 3, the resin films having a siloxane structure were measured for the level difference of via holes after the above step 6 (using a level difference meter P-15 manufactured by KLA-Tencor Co.). According to the measurement, very flat films were obtained, and shrinkage percentage of the resin films was 3% or less.

Further, formation of a Cu rewiring layer as the second layer having high flatness without vertical waviness was observed after the above step 7).

A performance comparison of the photosensitive resin compositions obtained in Examples 1 to 3 and Comparative Example 1 is shown in Table 1. Specifically, adhesion evaluation and elongation at break in Table 1 were based on the following measuring methods.

### <Adhesion Evaluation Method>

A resin film was formed on a Si wafer with a Cu sputter film by subjecting the wafer to the steps 1) through 6) in Examples 1 to 3 and Comparative Example 1. Then, the film was scored with a cutter knife so that 100 squares of 1 mm square might be created using a cross-cut guide 1.0 according to the cross-cut tape peeling test (JIS K 5400). A cellophane tape was stuck to the top of the film, and then it was peeled. Adhesion was evaluated by counting the number of the squares which did not adhere to the cellophane tape but was remaining on the substrate.

### <Evaluation Method of Elongation at Break>

A resin film was formed on a Si wafer with an Al sputter film by subjecting the wafer to the steps 1) through 6) in Examples 1 to 3 and Comparative Example 1. Then, the film was cut to a 3.0 mm wide strip using a dicing saw (Model DAD-2H/6T, manufactured by Disco Corporation). This wafer was immersed in a 10% hydrochloric acid water, and the resin film was peeled from the silicon wafer for using it as a strip of film sample. The film sample obtained was set in a measuring apparatus (Tensilon, model UTM-I I-20, manufactured by ORIENTEC Co., Ltd.) and measured under conditions of a distance between chucks of 50 mm and a tensile speed of 40 mm/min in accordance with the tensile strain at break test (JIS K 7161).

TABLE 1

| | | | | Comparative |
|---|---|---|---|---|
| | Example 1 | Example 2 | Example 3 | Example 1 |
| Adhesion | 100 pieces | 70 pieces | 80 pieces | 0 piece |
| evaluation | | | | |
| Elongation | 8% | 8% | 10% | 4% |
| at break | | | | |

### INDUSTRIAL APPLICABILITY

The photosensitive resin composition of the present invention and the resin film obtained from this photosensitive resin composition are very useful for electric and electronic materials such as semiconductor devices and multilayer interconnection boards, particularly a buffer coating material for LSI chips. This resin film can be used as an insulating resin film.

1. A photosensitive resin composition, comprising:
100 parts by weight of a polycondensate obtained by condensation-polymerizing compounds represented below by a) and b) in a mixing ratio of a)/b) of 60 mol %/40 mol % to 40 mol %/60 mol % for 0.1 to 10 hours at a temperature of 40 to 150° C.,
0.01 to 5 parts by weight of a photopolymerization initiator, and
1 to 30 parts by weight of at least one organosilane represented below by c),
wherein
a) represents R¹ₐR²_{b}Si(OR³)_{4-a-b}
wherein R¹ represents a group having 2 to 17 carbon atoms which contains at least one group selected from the group consisting of an epoxy group and a carbon-carbon double bond group; R² and R³ independently represent a methyl group or an ethyl group; a represents an integer selected from 1 and 2; b represents an integer selected from 0 and 1; and a+b does not exceed 2;
b) represents R₂Si(OH)₂
wherein R represents one or more groups selected from the group consisting of an aryl group having 6 to 20 carbon atoms and an alkylaryl group having 6 to 20 carbon atoms; and
c) represents R⁴Si(OR⁵)₃
wherein R⁴ represents an organic group containing a group having 2 to 17 carbon atoms which has any one of an epoxy group, an acrylic group, and a methacrylic group; and R⁵ is a methyl group or an ethyl group.

2. A photosensitive resin composition according to claim 1, characterized in that the compound a) is 3-methacryloxypropyltrimethoxysilane, and the compound b) is diphenylsilanediol.

3. A photosensitive resin composition according to claim 1, characterized in that the organosilane c) is at least one compound selected from the group consisting of 3-glycidyloxypropyltrimethoxysilane, 3-methacryloxypropyltrimethoxysilane, and 3-acryloxypropyltrimethoxysilane.

4. A process for producing a resin film having a siloxane structure, characterized by comprising the steps of coating the photosensitive resin composition according to claim 1 on a silicon wafer surface, exposing the coated film, developing the exposed film, and curing the developed film.

5. A layered resin article obtained by layering a resin film on a silicon wafer surface by the process for producing a resin film according to claim 4.

6. A photosensitive resin composition according to claim 2, characterized in that the organosilane c) is at least one compound selected from the group consisting of 3-glycidyloxypropyltrimethoxysilane, 3-methacryloxypropyltrimethoxysilane, and 3-acryloxypropyltrimethoxysilane.

7. A process for producing a resin film having a siloxane structure, characterized by comprising the steps of coating the photosensitive resin composition according to claim 2 on a silicon wafer surface, exposing the coated film, developing the exposed film, and curing the developed film.

8. A process for producing a resin film having a siloxane structure, characterized by comprising the steps of coating the photosensitive resin composition according to claim 3 on a silicon wafer surface, exposing the coated film, developing the exposed film, and curing the developed film.

9. A process for producing a resin film having a siloxane structure, characterized by comprising the steps of coating the photosensitive resin composition according to claim 6 on a silicon wafer surface, exposing the coated film, developing the exposed film, and curing the developed film.

10. A layered resin article obtained by layering a resin film on a silicon wafer surface by the process for producing a resin film according to claim 7.

11. A layered resin article obtained by layering a resin film on a silicon wafer surface by the process for producing a resin film according to claim 8.

12. A layered resin article obtained by layering a resin film on a silicon wafer surface by the process for producing a resin film according to claim 9.
